(19) United States
(12) Patent Application Publication
(10) Pub. No.: US 2025/0364801 A1
(43) Pub. Date: Nov. 27, 2025

(54) AUTOMATIC MONITORING GROUND FAULT CIRCUIT INTERRUPTER WITH INDEPENDENTLY DESIGNED TIPPING MECHANISM

(71) Applicant: Jiangsu Barep Smart Technology Co.,Ltd, Zhangjiagang (CN)

(72) Inventors: Jiangang Chen, Zhangjiagang (CN); Xiaobo Zheng, Zhangjiagang (CN)

(21) Appl. No.: 19/290,472

(22) Filed: Aug. 5, 2025

(30) Foreign Application Priority Data
Jul. 7, 2025 (CN) 202510927359.1

(51) Int. Cl. H02H 3/16; H02H 1/00

(52) U.S. Cl. CPC H02H 3/16; H02H 1/0007

(57) ABSTRACT

An automatic monitoring ground fault circuit interrupter with an independently designed tipping mechanism is provided. The automatic monitoring ground fault circuit interrupter includes: a neutral wire multiple grounding detection circuit, including a transformer coil, a chip IC1, and a bridge rectifier D4, where the transformer coil includes a leakage sensor transformer coil ZCT and a neutral wire multiple grounding sensor transformer coil CT, the transformer coil is connected to the chip IC1, and the bridge rectifier D4 is connected to a fifth pin of the chip; a manual leakage detection circuit; an automatic monitoring circuit, including a comparator, a current-limiting resistor R12, and a switching triode Q1, where an output end of the comparator is connected to a base electrode of the switching triode Q1 after in series connection with the current-limiting resistor R12.

### TECHNICAL FIELD

The present disclosure relates to the technical field of ground fault circuit interrupters, in particular to automatic monitoring ground fault circuit interrupter with an independently designed tipping mechanism.

### BACKGROUND

A ground fault circuit interrupter (GFCI) is a protection apparatus configured to detect an abnormal ground current of a circuit and quickly cut off a power supply. The ground fault circuit interrupter identifies a ground fault by detecting remaining current in the circuit. After the ground fault circuit interrupter detects the abnormal current, a signal processing circuit triggers an electromagnetic tripping mechanism and mechanically cuts off the circuit.

In an existing main control circuit of the ground fault circuit interrupter, an automatic monitoring circuit is complex in circuit, large in the quantity of components, high in costs of the components, and low in reliability, and a power supply connected to a load cannot be cut off in time.

### SUMMARY

The present disclosure aims to provide an automatic monitoring ground fault circuit interrupter with an independently designed tipping mechanism, so as to solve a problem that an automatic monitoring circuit in an existing main control circuit of the ground fault circuit interrupter is high in cost and low in reliability.

To achieve the above-mentioned objective, the present disclosure adopts the following technical solution. An automatic monitoring ground fault circuit interrupter with an independently designed tipping mechanism includes:
a neutral wire multiple grounding detection circuit, including a transformer coil, a chip IC1, and a bridge rectifier D4, where the transformer coil includes a leakage sensor transformer coil ZCT and a neutral wire multiple grounding sensor transformer coil CT, the transformer coil is connected to the chip IC1, and the bridge rectifier D4 is connected to a fifth pin of the chip;
a manual leakage detection circuit, including a resistor R14 and a micro switch TEST, where the resistor R14 is connected from a fire wire input end of a transformer assembly to an output neutral wire end of the transformer assembly;
an automatic monitoring circuit, including a comparator, a current-limiting resistor R12, and a switching triode Q1, where the comparator includes a chip IC2, a resistor R10, a resistor R11, a resistor R9, and a capacitor C8, the current-limiting resistor R12 is connected to a fourth pin of the chip IC2, and an output end of the comparator is connected to a base electrode of the switching triode Q1 after in series connection with the current-limiting resistor R12; and
an electromagnetic trip circuit, including a trip coil L2, a thyristor SCR1, a resistor R13, and a capacitor C9; where

after the ground fault circuit interrupter is powered on, the automatic monitoring circuit automatically and cyclically monitors based on specified interval time T; when the resistor R9 charges the capacitor C8, a voltage of the capacitor C8 exceeds a reference voltage of the comparator, and the comparator outputs a high voltage, so that the switching triode Q1 is turned on; the resistor R14 is grounded by using the switching triode Q1 to generate a current exceeding 6MA, and the transformer coil senses an unbalanced current exceeding 6MA, and is coupled to the chip IC1 by using the resistor R2 and the capacitor C2; a high level output by a seventh pin of the chip IC1 triggers the thyristor SCR1 to be turned on, and the thyristor SCR2 is connected to a diode D1 in series, so that the thyristor SCR2 is turned on in a lower half cycle, and an electromagnetic coil L1 is not able to be powered on; because the thyristor SCR1 is turned on, the comparator and the input end are quickly discharged by using a diode D3, so that an output end of the comparator becomes a low point position, and the switching triode Q is cut off to complete a monitoring cycle.

As further description of the above-mentioned technical solution, the ground fault circuit interrupter further includes a power supply circuit, the power supply circuit includes a resistor R5A, a resistor R5B, and a capacitor C5, and the resistor R5A and the resistor R5B are connected in parallel.

As further description of the above-mentioned technical solution, the ground fault circuit interrupter further includes a state display circuit, and the state display circuit includes a load voltage sampling circuit, a switching triode Q2, an indicator light LED1, and an indicator light LED2.

As further description of the above-mentioned technical solution, the load voltage sampling circuit includes a rectifier diode D5, a current-limiting resistor R16, and an optical coupler U1A, the indicator light LED2 is connected to an output end of the optical coupler U1A, a positive electrode of the indicator light LED1 is connected to the current-limiting resistor R16, and a negative electrode of the indicator light LED1 is connected to a collector electrode of the switching triode Q2.

In conclusion, because the above-mentioned technical solution is adopted, the present disclosure has the following beneficial effects.

Firstly, in the present disclosure, the ground fault circuit interrupter has a function of manually testing trip time and an automatic monitoring function. After a circuit fault is automatically detected, the power supply can be cut off automatically. The ground fault circuit interrupter implements the automatic monitoring function by using the automatic monitoring circuit. The automatic monitoring circuit includes a comparator circuit composed of at least one single operational amplifier. The ground fault circuit interrupter of the power supply can be cut off automatically when the circuit fault is automatically detected.

Secondly, in the present disclosure, a comparator output end in the automatic monitoring circuit is connected to a current-limiting resistor R12, so as to drive the switching triode Q1 to control the monitoring circuit including R14 to simulate leakage. By using a simple comparator circuit, various components in a leakage sensor, a neutral wire multiple grounding sensor, a dedicated chip, and a power supply circuit loop are automatically detected all the time, so as to avoid a safety accident caused by damage of the GFCI due to damage of components such as a power component and a trip coil, which is high in reliability and low in cost.

Thirdly, in the present disclosure, the electromagnetic trip circuit is independent of the main control circuit, and the electromagnetic trip circuit has an independent electromagnetic trip coil used for tripping and a drive circuit, so that a power supply connected to a load can be cut off in time when a damage fault is automatically monitored.

### BRIEF DESCRIPTION OF THE DRAWINGS

To describe the technical solutions in the embodiments of the present discourse more clearly, the following briefly describes the attached figures required for describing the embodiments. Apparently, the attached figures in the following descriptions show merely some embodiments of the present disclosure, and thus should not to be regarded as limitation of the scope; and a person of ordinary skill in the art may derive other attached figures from these attached figures without creative efforts.

FIG. 1 is a circuit diagram of an automatic monitoring ground fault circuit interrupter with an independently designed tipping mechanism;

FIG. 2 is a first schematic structural diagram of an automatic monitoring ground fault circuit interrupter with an independently designed tipping mechanism; and

FIG. 3 is a second schematic structural diagram of an automatic monitoring ground fault circuit interrupter with an independently designed tipping mechanism.

Reference signs in attached figures:
9: reset key; 91: reset key pull rod; 92: lifter; 93: trip coil iron core; and 94: terminal silver point.

### DETAILED DESCRIPTION OF THE EMBODIMENTS

To make the objectives, technical solutions, and advantages of the embodiments of the present disclosure clearer, the following clearly and completely describes the technical solutions in the embodiments of the present disclosure with reference to the attached figures in the embodiments of the present disclosure. Apparently, the described embodiments are some but not all of the embodiments of the present disclosure. Generally, the described and illustrated components of the embodiments of the present disclosure in the attached figures can be arranged and designed through various different configurations.

Therefore, the detailed description of the embodiments of the present disclosure provided in the attached figures is not intended to restrict the protected scope of the present disclosure, but merely represents the selected embodiment of the present disclosure. Based on the embodiment in the present disclosure, all other embodiments obtained by the ordinary technical staff in the art under the premise of without contributing creative labor belong to the scope protected by the present disclosure.

### Embodiment I

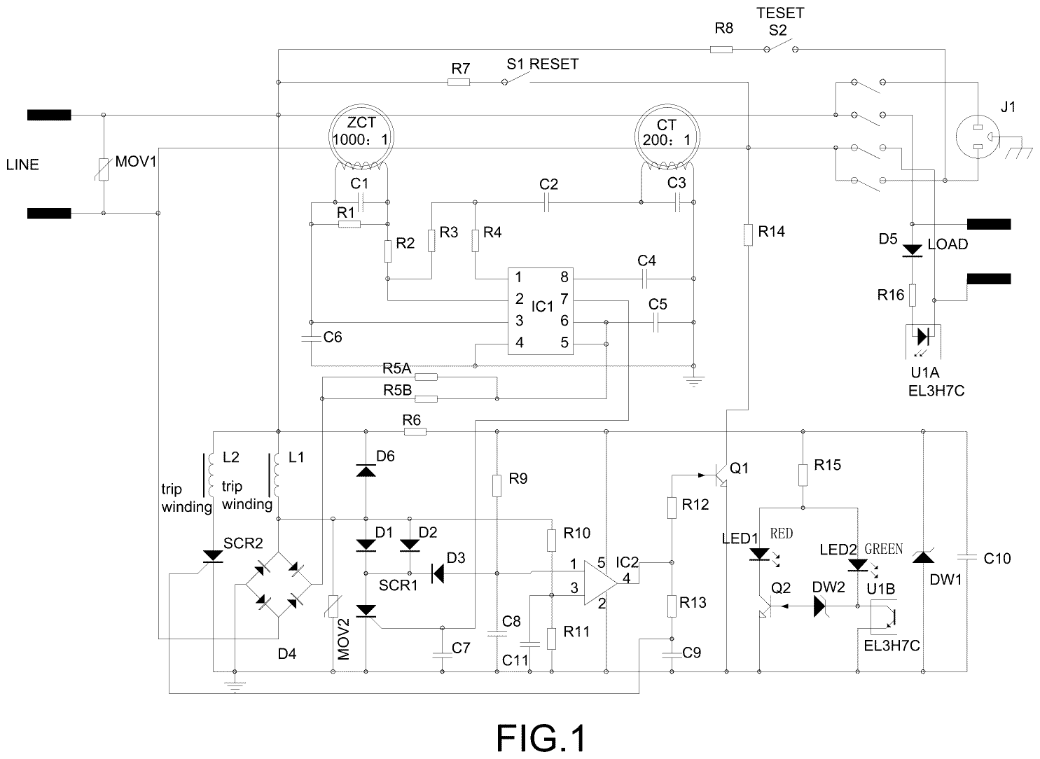

Referring to FIG. 1 to FIG. 3, the present disclosure provides a technical solution. An automatic monitoring ground fault circuit interrupter with an independently designed tipping mechanism includes:

a neutral wire multiple grounding detection circuit, including a transformer coil, a chip IC1, and a bridge rectifier D4, where the transformer coil includes a leakage sensor (1000:1) transformer coil ZCT and a neutral wire multiple grounding sensor (200:1) transformer coil CT, the transformer coil is connected to the chip IC1, and the bridge rectifier D4 is connected to a fifth pin of the chip;
a manual leakage detection (TEST) circuit, including a resistor R14 and a micro switch TEST, where the resistor R14 is connected from a fire wire input end of a transformer assembly to an output neutral wire end of the transformer assembly;
an automatic monitoring circuit, including a comparator, a current-limiting resistor R12, and a switching triode Q1, where the comparator includes a chip IC2, a resistor R10, a resistor R11, a resistor R9, and a capacitor C8, the current-limiting resistor R12 is connected to a fourth pin of the chip IC2, and an output end of the comparator is connected to a base electrode of the switching triode Q1 after in series connection with the current-limiting resistor R12; and
an electromagnetic trip circuit, including a trip coil L2, a thyristor SCR1, a resistor R13, and a capacitor C9; where
after the ground fault circuit interrupter is powered on, the automatic monitoring circuit automatically and cyclically monitors based on specified interval time T; when the resistor R9 charges the capacitor C8, a voltage of the capacitor C8 exceeds a reference voltage of the comparator, and the comparator outputs a high voltage, so that the switching triode Q1 is turned on; the resistor R14 is grounded by using the switching triode Q1 to generate a current exceeding 6MA, and the transformer coil senses an unbalanced current exceeding 6MA, and is coupled to the chip IC1 by using the resistor R2 and the capacitor C2; a high level output by a seventh pin of the chip IC1 triggers the thyristor SCR1 to be turned on, and the thyristor SCR2 is connected to a diode D1 in series, so that the thyristor SCR2 is turned on in a lower half cycle, and an electromagnetic coil L1 is not able to be powered on; because the thyristor SCR1 is turned on, the comparator and the input end are quickly discharged by using a diode D3, so that an output end of the comparator becomes a low point position, and the switching triode Q is cut off to complete a monitoring cycle.

By pressing a reset button RESET, an analog leakage resistor R14 connected to the micro switch TEST below the reset button RESET is turned on, so as to generate unbalanced current exceeding 6MA. The transformer coil senses the unbalanced current exceeding 6MA, and is coupled to the chip IC1 by using the resistor R2 and the capacitor C2. The seventh pin of the chip IC1 outputs a high level to trigger the thyristor SCR2, and a loop formed by the trip coil L2, the diode D1, the dipole D2, and the thyristor SCR1 is trigger to be turned on. The tripping mechanism is reset, and the power supply is turned on.

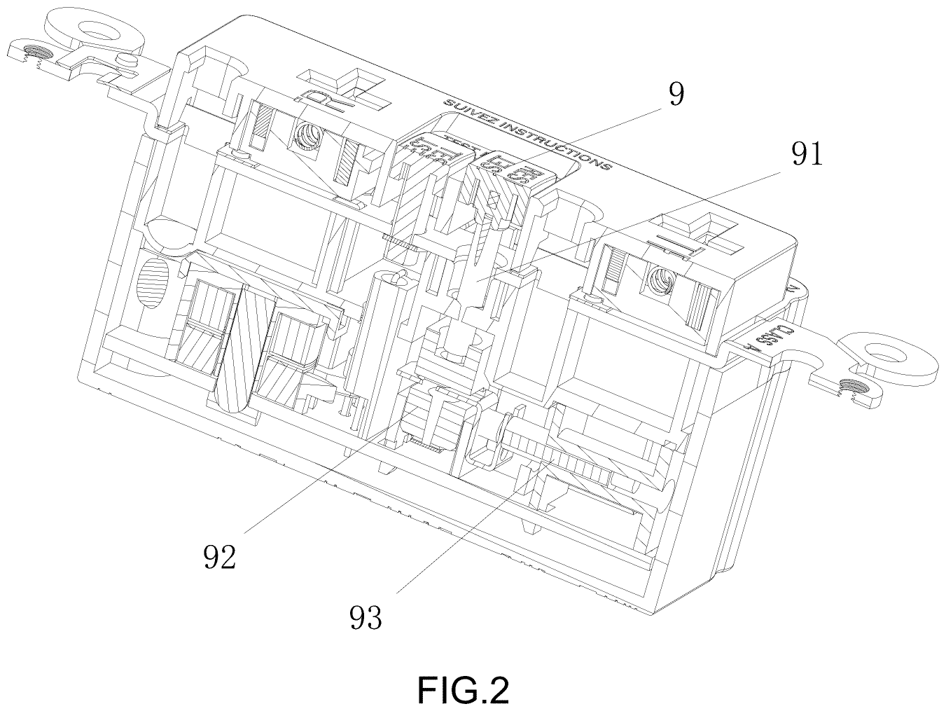

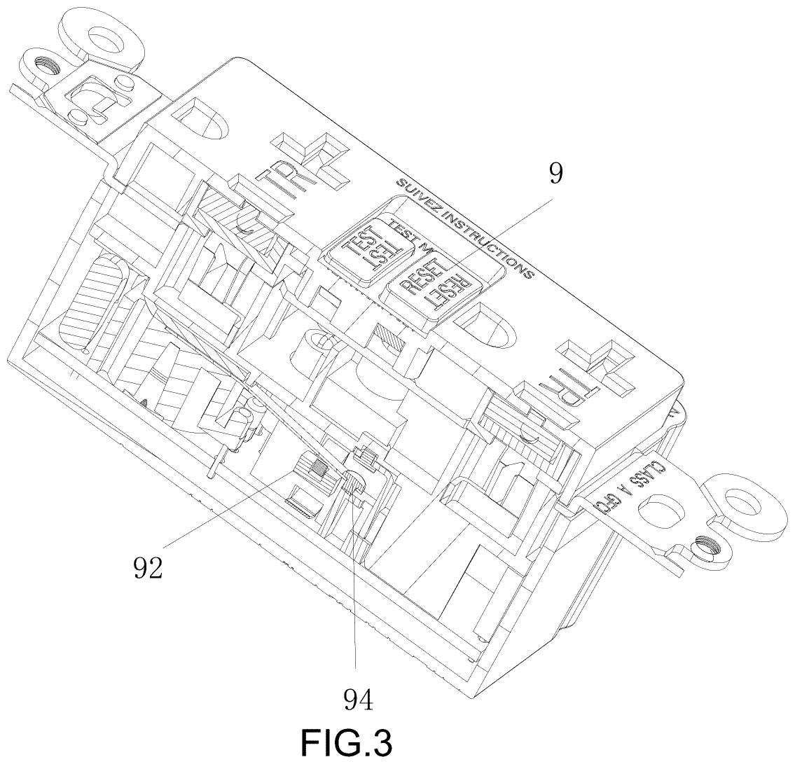

Referring to FIG. 2 and FIG. 3, by pressing a reset key 9, a reset key pull rod 91 presses a lock catch. The lock is installed in a lifter 92. By pressing the lifter 92, and the micro switch TEST is turned on. When the tripping mechanism is reset, a trip coil iron core 93 pushes a mechanical action, the iron core pulls the lock catch to act, so that the iron core of the reset button is hung to the lock catch. A lifter 92 is pulled by using main spring reaction force so as to be in contact with a terminal silver point 94, and a panel socket is connected to a power supply of a circuit load.

The present disclosure mainly protects a main control circuit and an electromagnetic trip circuit of the ground fault circuit interrupter. A specific structure and a reset process of the tripping mechanism are in the prior art and are not related to a protection theme. Details are not described. The tripping mechanism performs actions only based on a trip command generated by the electromagnetic trip circuit.

The ground fault circuit interrupter further includes a power supply circuit, the power supply circuit includes a resistor R5A, a resistor R5B, and a capacitor C5, and the resistor R5A and the resistor R5B are connected in parallel. The power supply circuit supplies power for the chip IC1.

The working principle is as follows. In the neutral wire multiple grounding detection circuit, when the transformer coil senses the unbalanced current exceeding 6MA or detects neutral wire multiple grounding, and the transformer coil is coupled to the chip IC1 by using the resistor R2 and the capacitor C2. The seventh pin of the chip IC1 outputs a high level to trigger the thyristor SCR2, and a loop formed by the trip coil L2, the diode D1, the dipole D2, and the thyristor SCR1 is trigger to be turned on. The iron core of the trip coil L2 in the electromagnetic trip circuit pushes the mechanical action. The tripping mechanism performs a tripping action to cut off the power supply.

The ground fault circuit interrupter has a function of manually testing trip time and an automatic monitoring function. After a circuit fault is automatically detected, the power supply can be cut off automatically. The ground fault circuit interrupter implements the automatic monitoring function by using the automatic monitoring circuit. The automatic monitoring circuit includes a comparator circuit composed of at least one single operational amplifier. The ground fault circuit interrupter of the power supply can be cut off automatically when the circuit fault is automatically detected.

A comparator output end in the automatic monitoring circuit is connected to a current-limiting resistor R12, so as to drive the switching triode Q1 to control the monitoring circuit including R14 to simulate leakage. By using a simple comparator circuit, various components in a leakage sensor, a neutral wire multiple grounding sensor, a dedicated chip, and a power supply circuit loop are automatically detected all the time, so as to avoid a safety accident caused by damage of the GFCI due to damage of components such as a power component and a trip coil, which is high in reliability and low in cost.

The electromagnetic trip circuit is independent of the main control circuit, and the electromagnetic trip circuit has an independent electromagnetic trip coil used for tripping and a drive circuit, so that a power supply connected to a load can be cut off in time when a damage fault is automatically monitored.

### Embodiment II

Based on the above-mentioned embodiment, the present disclosure further has the following as an improved technical solution. The ground fault circuit interrupter further includes a state display circuit, and the state display circuit includes a load voltage sampling circuit, a switching triode Q2, an indicator light LED1, and an indicator light LED2.

When a fault occurs in the ground fault circuit interrupter, the comparator of the automatic monitoring circuit is at a high level. The switching triode Q1 is turned on. The resistor R14 is grounded by using the switching triode Q1 to generate an unbalanced current exceeding 6MA. Because of the circuit fault, the seventh pin of the chip IC1 cannot output the high level, the thyristor SCR2 cannot be triggered, and a terminal voltage of the chip IC2 cannot be released. The fourth pin of the chip IC2 continuously outputs the high level. The capacitor C9 is continuously charged by using the resistor R13. When the voltage reaches a trigger voltage of triggering the thyristor SCR1, the thyristor SCR1 is turned on, and the electromagnetic coil L2 is switched on, so as to drive the iron end. In this case, the output end of the optical coupler U1A is in a cut-off state, and the green indicator light LED2 is not lighted. The switching triode Q2 is turned on at the high level, so as to light the red indicator light LED1.

The load voltage sampling circuit includes a rectifier diode D5, a current-limiting resistor R16, and an optical coupler U1A. The indicator light LED2 is connected to an output end of the optical coupler U1A. A positive electrode of the indicator light LED1 is connected to the current-limiting resistor R16, and a negative electrode of the indicator light LED1 is connected to a collector electrode of the switching triode Q2.

After the ground fault circuit interrupter (GFCI) is reset, the load is powered on. After rectification of the rectifier diode D5 and current limitation of the current-limiting resistor R16, the input end is driven, and the output end of the optical coupler U1A is controlled to turn on the green indicator light LED2.

When the ground fault circuit interrupter is in a trip state, the output end of the optical coupler U1A is in a cut-off state. The green indicator light LED2 and the switching triode Q2 are turned on at the high level, so as to light the red indicator light LED1.

Therefore, the ground fault circuit interrupter has clear trip state and reset state displays, so as to display the red indicator light in a trip state and display the green indicator light in a reset state.

The above mentioned are only preferred specific embodiments of the present disclosure. However, the scope of protection of the present disclosure is not limited to the embodiments described herein. Any technicians skilled in the technical field are within the technical scope disclosed by the present disclosure; and any replacements or modifications according to the technical solutions of the present disclosure and ideas thereof all shall be included in the scope of protection of the present disclosure.

What is claimed is:

1. An automatic monitoring ground fault circuit interrupter with an independently designed tipping mechanism, comprising:
a neutral wire multiple grounding detection circuit, comprising a transformer coil, a chip IC1, and a bridge rectifier D4, wherein the transformer coil comprises a leakage sensor transformer coil ZCT and a neutral wire multiple grounding sensor transformer coil CT, the transformer coil is connected to the chip IC1, and the bridge rectifier D4 is connected to a fifth pin of the chip;
a manual leakage detection circuit, comprising a resistor R14 and a micro switch TEST, wherein the resistor R14 is connected from a fire wire input end of a transformer assembly to an output neutral wire end of the transformer assembly;
an automatic monitoring circuit, comprising a comparator, a current-limiting resistor R12, and a switching triode Q1, wherein the comparator comprises a chip IC2, a resistor R10, a resistor R11, a resistor R9, and a capacitor C8, the current-limiting resistor R12 is connected to a fourth pin of the chip IC2, and an output end of the comparator is connected to a base electrode of the switching triode Q1 after in series connection with the current-limiting resistor R12; and
an electromagnetic trip circuit, comprising a trip coil L2, a thyristor SCR1, a resistor R13, and a capacitor C9; wherein
after the ground fault circuit interrupter is powered on, the automatic monitoring circuit automatically and cyclically monitors based on specified interval time T; when the resistor R9 charges the capacitor C8, a voltage of the capacitor C8 exceeds a reference voltage of the comparator, and the comparator outputs a high voltage, so that the switching triode Q1 is turned on; the resistor R14 is grounded by using the switching triode Q1 to generate a current exceeding 6MA, and the transformer coil senses an unbalanced current exceeding 6MA, and is coupled to the chip IC1 by using the resistor R2 and the capacitor C2; a high level output by a seventh pin of the chip IC1 triggers the thyristor SCR1 to be turned on, and the thyristor SCR2 is connected to a diode D1 in series, so that the thyristor SCR2 is turned on in a lower half cycle, and an electromagnetic coil L1 is not able to be powered on; because the thyristor SCR1 is turned on, the comparator and the input end are quickly discharged by using a diode D3, so that an output end of the comparator becomes a low point position, and the switching triode Q is cut off to complete a monitoring cycle.

2. The automatic monitoring ground fault circuit interrupter with an independently designed tipping mechanism according to claim 1, wherein the ground fault circuit interrupter further comprises a power supply circuit, the power supply circuit comprises a resistor R5A, a resistor R5B, and a capacitor C5, and the resistor R5A and the resistor R5B are connected in parallel.

3. The automatic monitoring ground fault circuit interrupter with an independently designed tipping mechanism according to claim 1, wherein the ground fault circuit interrupter further comprises a state display circuit, and the state display circuit comprises a load voltage sampling circuit, a switching triode Q2, an indicator light LED1, and an indicator light LED2.

4. The automatic monitoring ground fault circuit interrupter with an independently designed tipping mechanism according to claim 3, wherein the load voltage sampling circuit comprises a rectifier diode D5, a current-limiting resistor R16, and an optical coupler U1A, the indicator light LED2 is connected to an output end of the optical coupler U1A, a positive electrode of the indicator light LED1 is connected to the current-limiting resistor R16, and a negative electrode of the indicator light LED1 is connected to a collector electrode of the switching triode Q2.
